(19) United States
(12) Patent Application Publication
(10) Pub. No.: US 2023/0167295 A1
(43) Pub. Date: Jun. 1, 2023

(54) RESIN COMPOSITION, MOLDED PRODUCT, COMPOSITE AND ITS USE

(71) Applicant: AGC Inc., Tokyo (JP)

(72) Inventors: Norio OZAWA, Tokyo (JP); Toru SASAKI, Tokyo (JP); Masatoshi ABE, Tokyo (JP)

(73) Assignee: AGC Inc., Tokyo (JP)

(21) Appl. No.: 18/158,678

(22) Filed: Jan. 24, 2023

Related U.S. Application Data
(63) Continuation of application No. PCT/JP2021/029662, filed on Aug. 11, 2021.

(30) Foreign Application Priority Data
Aug. 14, 2020 (JP) 2020-136980
Dec. 9, 2020 (JP) 2020-204468

(51) Int. Cl. C08L 61/16

(52) U.S. Cl. CPC C08L 61/16; C08L 2201/08; C08L 2205/03

(57) ABSTRACT

To provide a molded product which has a high flexural modulus and is excellent in heat resistance and impact resistance at a low temperature; and a resin composition from which the molded product can be obtained.

A resin composition comprising a polyaryl ether ketone, a fluorinated elastomer and an inorganic filler, wherein the proportion of the fluorinated elastomer to the total of the volume of the polyaryl ether ketone and the volume of the fluorinated elastomer, is from 1 to 45 vol %, the proportion of the inorganic filler is from 1 to 50 mass %, and the deflection temperature under load measured in accordance with ASTM D648 under a load of 1.82 MPa is higher than that of the following comparative composition; and a molded product of the resin composition:

comparative composition: a resin composition comprising a polyaryl ether ketone and a fluorinated elastomer and not containing an inorganic filler, wherein the type of the polyaryl ether ketone, the type of the fluorinated elastomer and the proportion of the volume of the fluorinated elastomer to the total of the volume of the polyaryl ether ketone and the volume of the fluorinated elastomer are the same as those of the above resin composition, except that the inorganic filler is not contained.

### TECHNICAL FIELD

The present invention relates to a resin composition, a molded product, a composite and its application.

### BACKGROUND ART

Polyaryl ether ketone (polyether ether ketone, polyether ketone, polyether ketone ketone, etc.) is excellent in heat resistance and has a high flexural modulus. Polyaryl ether ketone is thereby widely used in various fields as a material for molded products.

However, the molded product of polyaryl ether ketone has insufficient impact resistance at room temperature or at a low temperature.

The following have been proposed as resin compositions from which a molded product having improved impact resistance can be formed.

A resin composition comprising a polyaryl ether ketone and a fluorinated elastomer, wherein the fluorinated elastomer is dispersed in the polyaryl ether ketone, the number average particle diameter of the fluorinated elastomer is from 1 to 300 μm, the volume ratio of the polyaryl ether ketone to the fluorinated elastomer is from 97:3 to 55:45, and the resin composition has a flexural modulus of from 1,000 to 3,700 MPa (Patent Document 1).

A resin composition comprising a polyaryl ether ketone and a fluorinated elastomer, wherein the ratio of the melt flow rate of the polyaryl ether ketone under the specific condition to that of the fluorinated elastomer is from 0.2 to 5.0, and the proportion of the volume of the polyaryl ether ketone to the total of the volume of the polyaryl ether ketone and the volume of the fluorinated elastomer, is from 60 to 97 vol % (Patent Document 2).

### PRIOR ART DOCUMENT

### Patent Document

Patent Document 1: WO2017/188280
Patent Document 2: WO2019/198771

### DISCLOSURE OF INVENTION

### Technical Problem

Since the resin compositions of Patent Documents 1 and 2 contain the fluorinated elastomer, a high flexural modulus of the polyaryl ether ketone may be impaired. Further, when a molded product is formed, the heat resistance is insufficient, and there is room for improvement of the impact resistance at a low temperature.

The present invention provides a molded product which has a high flexural modulus and which is excellent in the heat resistance and the impact resistance at a low temperature, and a resin composition from which such a molded product can be formed.

### Solution to Problem

As a result of extensive studies, the present inventors have found that the above object can be accomplished by a specific resin composition comprising a polyaryl ether ketone, a fluorinated elastomer and an inorganic filler.

Here, according to standard knowledge of those skilled in the art, it is expected that if three components of a polyaryl ether ketone, a fluorinated elastomer and an inorganic filler are used, the heat resistance and the flexural modulus of a molded product are lower than those of a composition comprising two components of a polyaryl ether ketone and an inorganic filler.

However, unexpectedly, the present inventors have found that the heat resistance, the flexural modulus and the impact resistance at a low temperature of a molded product of a resin composition comprising a polyaryl ether ketone, a fluorinated elastomer and an inorganic filler are more improved, beyond standard expectation of those skilled in the art, than a resin composition comprising two components of a polyaryl ether ketone and an inorganic file. Thus, the present invention has been accomplished.

### Solution to Problem

The present invention has the following embodiments.

[1] A resin composition comprising a polyaryl ether ketone, a fluorinated elastomer and an inorganic filler, wherein the proportion of the volume of the fluorinated elastomer to the total of the volume of the polyaryl ether ketone and the volume of the fluorinated elastomer, is from 1 to 45 vol %, the proportion of the mass of the inorganic filler to the resin composition is from 1 to 50 mass %, and the deflection temperature under load measured in accordance with ASTM D648 under a load of 1.82 MPa is higher than the deflection temperature under load of the following comparative composition:

comparative composition: a resin composition comprising the above polyaryl ether ketone and the above fluorinated elastomer and not containing the above inorganic filler, wherein the type of the polyaryl ether ketone, the type of the fluorinated elastomer and the proportion of the volume of the fluorinated elastomer to the total of the volume of the polyaryl ether ketone and the volume of the fluorinated elastomer are the same as those of the above resin composition, except that the inorganic filler is not contained.

[2] The resin composition according to [1], wherein the fluorinated elastomer is a copolymer having units based on tetrafluoroethylene and units based on propylene, a copolymer having units based on hexafluoropropylene and units based on vinylidene fluoride or a copolymer having units based on tetrafluoroethylene and units based on a compound represented by the following formula (1):

CF₂═CF(OR^{F}) (1)

where R^{F} is a C₁₋₈ linear or branched perfluoroalkyl group.
[3] The resin composition according to [1] or [2], wherein the polyaryl ether ketone is a polyether ketone, a polyether ether ketone or a polyether ketone ketone.
[4] The resin composition according to any one of [1] to [3], wherein the lightness L* in the hue measurement in accordance with JIS-Z8781-4 is at least 60.
[5] The resin composition according to any one of [1] to [4], wherein the inorganic filler is a fibrous inorganic filler, a flat plate inorganic filler or a particulate inorganic filler.
[6] The resin composition according to any one of [1] to [5], which contains as the inorganic filler, at least one member selected from the group consisting of carbon fiber, graphite, carbon nanotube, glass fiber and silica.
[7] The resin composition according to any one of [1] to [6], which contains as at least a part of the inorganic filler, carbon fiber or glass fiber.
[8] The resin composition according to any one of [1] to [7], which further contains a polymer filler.
[9] The resin composition according to [8], wherein the polymer filler is a polytetrafluoroethylene.
[10] The resin composition according to any one of [1] to [9], which further contains at least one member selected from the group consisting of a plasticizer, an ultraviolet absorber and a light stabilizer.
[11] A molded product obtained by molding the resin composition as defined in any one of [1] to [10].
[12] A composite comprising the molded product as defined in [11] combined or laminated with another material.
[13] A mobile electronic device, a sliding member, a three-dimensional electronic circuit component, an electric wire or a member for energy resource drilling, which is provided with the molded product as defined in [11] or the composite as defined in [12].

### Advantageous Effects of Invention

According to the resin composition of the present invention, a molded product which has a high flexural modulus and which is excellent in the heat resistance and the impact resistance at a low temperature can be obtained.

The molded product of the present invention has a high flexural modulus and is excellent in the heat resistance and the impact resistance at a low temperature.

### DESCRIPTION OF EMBODIMENTS

The meanings and definitions of the terms in the present specification are as follows.

The “volume” of the polyaryl ether ketone or the fluorinated elastomer is a value calculated by dividing the mass (g) of the polyaryl ether ketone or the fluorinated elastomer by its specific gravity (g/cm³).

The “specific gravity” of the polyaryl ether ketone or the fluorinated elastomer is a value measured at 23° C. by an underwater replacement (suspension) method.

The “number average particle diameter” of the fluorinated elastomer in the resin composition is a value obtained by measuring the maximum diameters of 100 particles randomly selected by observing a molded product of the resin composition by a scanning electron microscope, and arithmetically averaging them.

The “number average particle diameter” of the fluorinated elastomer before melt-kneading is a value obtained by measuring the maximum diameters of 100 particles randomly selected by observing the fluorinated elastomer by an optical microscope, and arithmetically averaging them.

The “flexural modulus” of the molded product is a value measured in accordance with ASTM D790.

The “melting point” of the polyaryl ether ketone is a temperature corresponding to the maximum value of the melting peak measured by a differential scanning calorimetry (DSC) method.

The “fluorine content” in the fluorinated elastomer indicates the ratio of the mass of fluorine atoms to the total mass of all atoms constituting the fluorinated elastomer. The fluorine content is a value calculated from the molar ratios of the respective units in the fluorinated elastic copolymer, obtained by melt NMR measurement and total fluorine content measurement.

The “Mooney viscosity (ML₁₊₁₀, 121° C.)” of the fluorinated elastomer is a value measured in accordance with JIS K6300-1: 2000 (corresponding international standard ISO 289-1: 2005, ISO 289-2: 1994).

A “unit based on a monomer” is a generic term for an atomic group directly formed by polymerization of one molecule of the monomer and an atomic group obtainable by chemically converting a part of said atomic group. In the present specification, a unit based on a monomer is simply referred to also as a monomer unit. For example, a unit based on TFE is referred to also as a TFE unit.

A “monomer” means a compound having a polymerizable carbon-carbon double bond.

### <Resin Composition>

The resin composition of the present invention comprises a polyaryl ether ketone, a fluorinated elastomer and an inorganic filler.

The resin composition of the present invention may contain components (hereinafter referred to as “other components”) other than the polyaryl ether ketone, the fluorinated elastomer and the inorganic filler, as the case requires, within a range not impair the effects of the present invention.

The deflection temperature T₀ under load of the resin composition of the present invention is higher than the deflection temperature T₁ under load of the following comparative composition (1). The deflection temperature T₀ under load of the resin composition of the present invention is a value measured in accordance with ASTM D648 under a load of 1.82 MPa.

Comparative composition (1): A resin composition comprising a polyaryl ether ketone and a fluorinated elastomer and not containing an inorganic filler, wherein the type of the polyaryl ether ketone, the type of the fluorinated elastomer and the proportion of the volume of the fluorinated elastomer to the total V_{A+B} of the volume of the polyaryl ether ketone and the volume of the fluorinated elastomer are the same as those of the resin composition of the present invention, except that the inorganic filler is not contained.

In a case where the resin composition of the present invention contains no other component, the comparative composition (1) is a composition consisting of a polyaryl ether ketone and a fluorinated elastomer. Accordingly, the composition of the comparative composition (1) can be determined based on the volume of the polyaryl ether ketone and the volume of the fluorinated elastomer in the resin composition of the present invention.

In a case where the resin composition of the present invention contains other components, the comparative composition (1) is a composition comprising a polyaryl ether ketone, a fluorinated elastomer and other components. In such a comparative composition (1), the content of other components is the same as the content of other components in the resin composition of the present invention, in all cases of the content to the polyaryl ether ketone, the content to the fluorinated elastomer and the content to the total content of them.

Here, the polyaryl ether ketone, the fluorinated elastomer and other components in the comparative composition (1) are the same as the polyaryl ether ketone, the fluorinated elastomer and other components in the resin composition of the present invention respectively. Accordingly, the deflection temperature T₁ under load of the comparative composition (1) having a composition to be determined based on the composition of the resin composition of present invention is a value measured in accordance with ASTM D648 under a load of 1.82 MPa.

The lower limit value of the difference: (T₀-T₁) between the deflection temperature T₀ under load and the deflection temperature T₁ under load is higher than 0° C., preferably at least 40° C., more preferably at least 60° C., further preferably at least 80° C., most preferably at least 100° C. When T₀-T₁ is at least the lower limit value, the heat resistance of a molded product will be further excellent. The higher the upper limit value of T₀-T₁ is, the better, and the upper limit value is not particularly limited. T₀-T₁ may, for example, be at most 180° C. or at most 160° C.

The lower limit value of the deflection temperature T₀ under load of the resin composition of the present invention is not particularly limited, so long as it is a value higher than the deflection temperature T₁ under load, however, it is preferably at least 160° C., more preferably at least 180° C., further preferably at least 200° C., most preferably at least 240° C. When the deflection temperature T₀ under load is at least the lower limit value, the heat resistance of a molded product will be further excellent. The higher the upper limit value of the deflection temperature T₀ under load is, the better, and it is not particularly limited. The deflection temperature T₀ under load may, for example, be at most 330° C. or at most 320° C.

The deflection temperature T₀ under load of the resin composition of the present invention is preferably higher than the deflection temperature T₂ under load of the following comparative composition (2).

Comparative composition (2): A resin composition comprising a polyaryl ether ketone and an inorganic filler and containing no fluorinated elastomer, wherein the type of the polyaryl ether ketone and the type of the inorganic filler are the same as those in the composition of the present invention, the volume of the polyaryl ether ketone is the same as the total V_{A+B} of the volume of the polyaryl ether ketone and the volume of the fluorinated elastomer in the resin composition of the present invention, and the proportion of the mass of the inorganic filler is the same as the proportion of the mass of the inorganic filler in the resin composition of the present invention.

In a case where the resin composition of the present invention contains no other component, the comparative composition (2) is a composition consisting of a polyaryl ether ketone and an inorganic filler. Accordingly, the composition of the comparative composition (2) can be determined based on the volume of the polyaryl ether ketone, the volume of the fluorinated elastomer and the mass of the inorganic filler in the resin composition of the present invention.

In a case where the resin composition of the present invention contains other components, the composition of the comparative composition (2) can be determined based on the volume of the polyaryl ether ketone, the volume of the fluorinated elastomer, the amount of other components and the mass of the inorganic filler in the resin composition of the present invention.

Here, the polyaryl ether ketone, the inorganic filler and other components in the comparative composition (2) are the same as the polyaryl ether ketone, the inorganic filler and other components in the resin composition of the present invention respectively. Accordingly, the deflection temperature T₂ under load of the comparative composition (2) having a composition to be determined based on the composition of the resin composition of present invention is a value measured in accordance with ASTM D648 under a load of 1.82 MPa.

The lower limit value of the difference: (T₀-T₂) between the deflection temperature T₀ under load and the deflection temperature T₂ under load is preferably higher than 0° C., more preferably at least 5° C., further preferably at least 10° C., particularly preferably at least 15° C., most preferably at least 20° C. When T₀-T₂ is at least the lower limit value, the heat resistance of a molded product will be further excellent. In general, it is expected that if three components of a polyaryl ether ketone, a fluorinated elastomer and an inorganic filler are used, due to the fluorinated elastomer, the heat resistance is inferior to that of a composition comprising two components of a polyaryl ether ketone and an inorganic filler. Therefore, if the deflection temperature T₀ under load is higher than the deflection temperature T₂ under load, the heat resistance of a molded product is remarkably excellent, contrary to expectations of those skilled in the art. The higher the upper limit value of T₀-T₂ is, the better, and the upper limit value is not particularly limited. T₀-T₂ may, for example, be at most 80° C. or at most 70° C.

The proportion of the volume of the fluorinated elastomer to the total of the volume of the polyaryl ether ketone and the volume of the fluorinated elastomer is from 1 to 45 vol %, preferably from 2 to 42 vol %, more preferably from 3 to 40 vol %, further preferably from 5 to 35 vol %. When the proportion of the volume of the fluorinated elastomer is at least the lower limit value in the above range, a molded product which is excellent in the impact resistance will be obtained. When the proportion of the volume of the fluorinated elastomer is at most the upper limit value in the above range, a molded product which is excellent in the heat resistance and the mechanical properties will be obtained.

The proportion of the total of the volume of the polyaryl ether ketone and the volume of the fluorinated elastomer to the volume of the resin composition excluding the volume of the inorganic filler is preferably from 50 to 100 vol %, more preferably from 60 to 100 vol %, further preferably from 70 to 100 vol %. When the proportion is less than 100 vol %, the resin composition contains other components.

When the total of the volume of the polyaryl ether ketone and the volume of the fluorinated elastomer is at least the lower limit value in the above range, a molded product will have sufficient heat resistance, mechanical properties and impact resistance. When the resin composition contains other components, and the proportion of the total of the volume of the polyaryl ether ketone and the volume of the fluorinated elastomer to the volume of the resin composition excluding the volume of the inorganic filler is at most 99 vol %, additional properties derived from other components can be imparted to the molded product.

The proportion of the mass of the inorganic filler to the resin composition of the present invention is from 1 to 50 mass %, preferably from 5 to 45 mass %, more preferably from 5 to 40 mass %, further preferably from 10 to 40 mass %. When the proportion of the mass of the inorganic filler is at least the lower limit value, a molded product will be excellent in the heat resistance and the impact resistance at low temperature and will have a high flexural modulus. Further, the deflection temperature T₀ under load will be higher than the deflection temperature T₁ under load. When the proportion of the mass of the inorganic filler is at most the upper limit value, the flowability at the time of molding will be excellent, and the resin composition of the present invention will be easily molded.

In the resin composition of the present invention, the fluorinated elastomer is preferably dispersed in the polyaryl ether ketone, with a view to improving the molding processability of the resin composition.

The number average particle size of the dispersed fluorinated elastomer is preferably from 0.5 to 10 μm, more preferably from 1 to 5 μm. When the number average particle size of the fluorinated elastomer is at least the lower limit value in the above range, the impact resistance of the fluorinated elastomer in the resin composition can be sufficiently obtained. When the number average particle size of the fluorinated elastomer is at most the upper limit value in the above range, the fluorinated elastomer can be uniformly dispersed in the polyaryl ether ketone.

Of the resin composition of the present invention, the flexural modulus when formed into a test specimen having a thickness of 4.0 mm, is preferably at least 3 GPa, more preferably at least 3.5 GPa, further preferably at least 4 GPa, particularly preferably at least 4.5 GPa. When the flexural modulus is at least the lower limit value, the mechanical properties of a molded product will be further excellent. The upper limit value of the flexural modulus is not particularly limited and may, for example, be at most 15 GPa or at most 13 GPa.

Of the resin composition of the present invention, the bending strength when formed into a test specimen having a thickness of 4.0 mm, is preferably at least 110 MPa, more preferably at least 120 MPa, further preferably at least 130 MPa, particularly preferably at least 140 MPa. When the bending strength is at least the lower limit value, the mechanical properties of a molded product will be further excellent. The upper limit value of the bending strength is not particularly limited and may, for example, be at most 250 MPa or at most 240 MPa.

Of the resin composition of the present invention, the Izod impact strength at −40° C. when formed into a test specimen having a thickness of 4.0 mm, is preferably at least 0.6 J/cm, more preferably at least 0.65 J/cm, further preferably at least 0.7 J/cm, particularly preferably at least 0.75 J/cm. When the Izod impact strength at −40° C. is at least the lower limit value, the impact resistance of a molded product at a low temperature will be further excellent. The upper limit value of the Izod impact strength at −40° C. is not particularly limited and may, for example, be at most 1.5 J/cm or at most 1.2 J/cm.

Of the resin composition of the present invention, the Izod impact strength at 23° C. when formed into a test specimen having a thickness of 4.0 mm, is preferably at least 0.6 J/cm, more preferably at least 0.65 J/cm, further preferably at least 0.7 J/cm, particularly preferably at least 0.75 J/cm. When the Izod impact strength at 23° C. is at least the lower limit value, the impact resistance of a molded product at ordinary temperature will be further excellent. The upper limit value of the Izod impact strength at 23° C. is not particularly limited and may, for example, be at most 1.6 J/cm or at most 1.3 J/cm.

Of the resin composition of the present invention, the lightness L* in the hue measurement of an injection-molded plate having a thickness of 4 mm in accordance with JIS-Z8781-4 is preferably at least 60, more preferably at least 65, further preferably at least 70, further more preferably at least 75, particularly preferably at least 80. When L* is at least the lower limit value, a molded product will be excellent in the lightness. The upper limit value of L* is 100.

### (Polyaryl Ether Ketone)

As the polyaryl ether ketone, from the viewpoint of mechanical properties and heat resistance, polyether ketone (hereinafter referred to also as “PEK”), polyether ether ketone (hereinafter referred to also as “PEEK”) or polyether ketone ketone (hereinafter referred to also as “PEKK”) is preferred, and PEEK is particularly preferred.

The polyether ether ketone may, for example, be VictrexPEEK (manufactured by Victrex plc.), VestaKeep (manufactured by EVONIK Industries) or Ketaspire (manufactured by Solvay specialty polymers). However, the polyether ketone ketone is not restricted to such examples.

The polyether ketone ketone may, for example, be Kepstan (manufactured by Arkema S.A.). However, the polyether ketone ketone is not restricted to such an example.

As the polyaryl ether ketone, two or more types may be used in combination, but it is preferred to use one type alone.

The melting point of the polyaryl ether ketone is preferably from 200 to 430° C., more preferably from 250 to 400° C., further preferably from 280 to 380° C. When the melting point of the polyaryl ether ketone is at least the lower limit value in the above range, the heat resistance of a molded product will be further excellent. When the melting point of the polyaryl ether ketone is at most the upper limit value in the above range, it is possible to suppress deterioration of physical properties due to thermal decomposition of the fluorinated elastomer at the time of melt-kneading, and it is possible to maintain the properties (impact resistance, chemical resistance, etc.) of the fluorinated elastomer.

The polyaryl ether ketone may be one which is commercially available, or may be one produced from various raw materials by a known method.

### (Fluorinated Elastomer)

The fluorinated elastomer is preferably a fluorinated elastic copolymer having units based on at least one type of monomer (hereinafter referred to also as “monomer (m1)”) selected from the group consisting of tetrafluoroethylene (hereinafter referred to also as “TFE”), hexafluoropropylene (hereinafter referred to also as “HFP”), vinylidene fluoride (hereinafter referred to also as “VdF”) and chlorotrifluoroethylene (hereinafter referred to also as “CTFE”).

The fluorinated elastomer is an elastic copolymer having no melting point and showing a storage elastic modulus G′ of at least 80 at 100° C. and 50 cpm as measured in accordance with ASTM D6204, and is distinguished from a fluororesin.

As the fluorinated elastomer, two or more types may be used in combination, but it is preferred to use one type alone.

The fluorinated elastomer may be a fluorinated elastic copolymer composed solely of two or three types of units selected from the group consisting of TFE units, HFP units, VdF units and CTFE units, or may be a fluorinated elastic copolymer comprising units based on the monomer (m1) and at least one type of units based on the following monomer (m2) which is copolymerizable with the monomer (m1).

The monomer (m2) is a monomer selected from the group consisting of ethylene (hereinafter referred to also as “E”), propylene (hereinafter referred to also as “P”), a perfluoro(alkyl vinyl ether) (hereinafter referred to also as “PAVE”), vinyl fluoride (hereinafter referred to also as “VF”), 1,2-difluoroethylene (hereinafter referred to also as “DiFE”), 1,1,2-trifluoroethylene (hereinafter referred to as “TrFE”), 3,3,3-trifluoro-1-propylene (hereinafter referred to also as “TFP”), 1,3,3,3-tetrafluoropropylene and 2,3,3,3-tetrafluoropropylene.

PAVE is a compound represented by the following formula (1).

CF₂═CF(OR^{F}) (1)

where R^{F} is a C₁₋₈ linear or branched perfluoroalkyl group.

PAVE may be perfluoro(methyl vinyl ether) (hereinafter referred to also as “PMVE”), perfluoro(ethyl vinyl ether) (hereinafter referred to also as “PEVE”), perfluoro(propyl vinyl ether) (hereinafter referred to also as “PPVE”) or perfluoro(butyl vinyl ether) (hereinafter referred to also as “PBVE”).

The fluorinated elastomer may have at least one type of units based on a monomer (hereinafter referred to also as “monomer (m3)”) other than the monomer (m1) and the monomer (m2), which is copolymerizable with the monomer (m1) and of which the copolymer with the monomer (m1) becomes an elastic copolymer.

The proportion of units based on the monomer (m3) is preferably from 0 to 20 mol %, more preferably from 0 to 5 mol %, particularly preferably 0 mol %, in all units constituting the fluorinated elastomer.

In the fluorinated elastomer, it is preferred that all units constituting the fluorinated elastomer are composed of two or three types of units based on the monomer (m1), or composed of at least one type of units based on the monomer (m1) and at least one type of units based on the monomer (m2). However, units other than these may be contained, as impurities, etc., so long as they do not affect the properties of the resin composition of the present invention.

A fluorinated elastic copolymer composed of two or three types of units based on the monomer (m1), and a fluorinated elastic copolymer composed of at least one type of units based on the monomer (m1) and at least one type of units based on the monomer (m2), will contribute to the impact resistance of the molded product.

As the fluorinated elastomer, the following three types of copolymers may be mentioned. The total proportion of the respective units specifically shown in the following three types of copolymers, is preferably at least 50 mol %, to all units constituting the copolymers.

A copolymer having TFE units and P units (hereinafter referred to also as “TFE/P-containing copolymer”),

A copolymer having HFP units and VdF units (but excluding one having P units) (hereinafter referred to also as “HFP/VdF-containing copolymer”),

A copolymer having TFE units and PAVE units (but excluding one having P units or VdF units) (hereinafter referred to also as “TFE/PAVE-containing copolymer).

As the TFE/P-containing copolymer, the following ones may be mentioned.

TFE/P (meaning a copolymer composed of TFE units and P units; the same applies to others), TFE/P/VF, TFE/P/VdF, TFE/P/E, TFE/P/TFP, TFE/P/PAVE, TFE/P/1,3,3,3-tetrafluoropropene, TFE/P/2,3,3,3-tetrafluoropropene, TFE/P/TrFE, TFE/P/DiFE, TFE/P/VdF/TFP, and TFE/P/VdF/PAVE may be mentioned, and among them, TFE/P is preferred.

The HFP/VdF-containing copolymer may be HFP/VdF, TFE/VdF/HFP, TFE/VdF/HFP/TFP, TFE/VdF/HFP/PAVE, VdF/HFP/TFP and VdF/HFP/PAVE. Among them, HFP/VdF is preferred.

The TFE/PAVE-containing copolymer may be TFE/PAVE, and particularly, TFE/PMVE and TFE/PMVE/PPVE are preferred where PAVE is PMVE or PPVE, and among them, TFE/PMVE is preferred.

Other examples of the fluorinated elastomer may be TFE/VdF/2,3,3,3-tetrafluoropropylene, VdF/PAVE, VdF/2,3,3,3-tetrafluoropropylene, and E/HFP.

As the fluorinated elastomer, a TFE/P-containing copolymer, a HFP/VdF-containing copolymer and a TFE/PAVE-containing copolymer are preferred, a TFE/P-containing copolymer is more preferred, and TFE/P is particularly preferred. TFE/P has good thermal stability at the time of melt-kneading and stable transportability at the time of melt-kneading. Further, coloring and foaming of a molded product of the present invention will be reduced.

The ratio of the respective units constituting the fluorinated elastomer is preferably in the following range with a view to readily contributing to the impact resistance of a molded product.

The molar ratio of the respective units in TFE/P (TFE:P, the same applies below) is preferably 30 to 80:70 to 20, more preferably 40 to 70:60 to 30, further preferably 60 to 50:40 to 50.

In TFE/P/VF, TFE:P:VF is preferably 30 to 60:60 to 20:0.05 to 40.

In TFE/P/VdF, TFE:P:VdF is preferably 30 to 60:60 to 20:0.05 to 40.

In TFE/P/E, TFE:P:E is preferably 20 to 60:70 to 30:0.05 to 40.

In TFE/P/TFP, TFE:P:TFP is preferably 30 to 60:60 to 30:0.05 to 20.

In TFE/P/PAVE, TFE:P:PAVE is preferably 40 to 70:60 to 29.95:0.05 to 20.

In TFE/P/1,3,3,3-tetrafluoropropene, TFE:P:1,3,3,3-tetrafluoropropene is preferably 30 to 60:60 to 20:0.05 to 40.

In TFE/P/2,3,3,3-tetrafluoropropene, TFE:P:2,3,3,3-tetrafluoropropene is preferably 30 to 60:60 to 20:0.05 to 40.

In TFE/P/TrFE, TFE:P:TrFE is preferably 30 to 60:60 to 20:0.05 to 40.

In TFE/P/DiFE, TFE:P:DiFE is preferably 30 to 60:60 to 20:0.05 to 40.

In TFE/P/VdF/TFP, TFE:P:VdF:TFP is preferably 30 to 60:60 to 20:0.05 to 40:0.05 to 20.

In TFE/P/VdF/PAVE, TFE:P:VdF:PAVE is preferably 30 to 70:60 to 20:0.05 to 40:0.05 to 20.

In HFP/VdF, HFP:VdF is preferably 99 to 5:1 to 95.

In TFE/VdF/HFP, TFE:VdF:HFP is preferably 20 to 60:1 to 40:20 to 60.

In TFE/VdF/HFP/TFP, TFE:VdF:HFP:TFP is preferably 30 to 60:0.05 to 40:60 to 20:0.05 to 20.

In TFE/VdF/HFP/PAVE, TFE:VdF:HFP:PAVE is preferably 30 to 70:60 to 20:0.05 to 40:0.05 to 20.

In VdF/HFP/TFP, VdF:HFP:TFP is preferably 1 to 90:95 to 5:0.05 to 20.

In VdF/HFP/PAVE, VdF:HFP:PAVE is preferably 20 to 90:9.95 to 70:0.05 to 20.

In TFE/PAVE, TFE:PAVE is preferably 40 to 70:60 to 30.

When PAVE is PMVE, TFE:PMVE is preferably 40 to 70:60 to 30.

In TFE/PMVE/PPVE, TFE:PMVE:PPVE is preferably 40 to 70:3 to 57:3 to 57.

In TFE/VdF/2,3,3,3-tetrafluoropropylene, TFE:VdF:2,3,3,3-tetrafluoropropylene is preferably 1 to 30:30 to 90:5 to 60.

In VdF/PAVE, VdF:PAVE is preferably 3 to 95:97 to 5.

In VdF/2,3,3,3-tetrafluoropropylene, VdF:2,3,3,3-tetrafluoropropylene is preferably 30 to 95:70 to 5.

In E/HFP, E:HFP is preferably 40 to 60:60 to 40.

The fluorine content in the fluorinated elastomer is preferably from 50 to 74 mass %, more preferably from 55 to 70 mass %. The fluorine content is preferably from 57 to 60 mass % in TFE/P, from 66 to 71 mass % in HFP/VdF, and from 66 to 70 mass % in TFE/PMVE. When the fluorine content is at least the lower limit value in the above ranges, the heat resistance and chemical resistance of a molded product will be further excellent. When the fluorine content is at most the upper limit value in the above ranges, the impact resistance of a molded product will be further excellent.

The number average molecular weight of the fluorinated elastomer is preferably from 10,000 to 1,500,000, more preferably from 20,000 to 1,000,000, further preferably from 20,000 to 800,000, particularly preferably from 50,000 to 600,000. When the number average molecular weight of the fluorinated elastomer is at least the lower limit value in the above range, the mechanical properties of a molded product will be further excellent. When the number average molecular weight of the fluorinated elastomer is at most the upper limit value in the above range, the flowability will be high, the dispersion in the polyaryl ether ketone will be good, and the impact resistance of a molded product will be further excellent.

The Mooney viscosity (ML₁₊₁₀, 121° C.) of the fluorinated elastomer is preferably from 20 to 200, more preferably from 30 to 150, further preferably from 40 to 120. The Mooney viscosity is an index for the molecular weight. A high Mooney viscosity shows a high molecular weight, and a low Mooney viscosity shows a low molecular weight. When the Mooney viscosity is within the above range, the molding processability of a resin composition will be further excellent, and the mechanical properties of a molded product will be further excellent.

The fluorinated elastomer can be produced by polymerizing at least one type of monomer (m1) and optionally at least one type of one or both of monomer (m2) and monomer (m3).

The polymerization method may be an emulsion polymerization method, a solution polymerization method, a suspension polymerization method, a bulk polymerization method, etc. An emulsion polymerization method in which monomers are polymerized in the presence of an aqueous medium and an emulsifier, is preferred, since adjustment of the number average molecular weight of the fluorinated elastic copolymer and the copolymer composition will be easy and the productivity will be excellent.

In the emulsion polymerization method, monomers are polymerized in the presence of an aqueous medium, an emulsifier and a radical polymerization initiator to obtain an elastomer latex. A pH adjusting agent may be added at the time of the polymerization of the monomers.

### (Inorganic Filler)

The shape of the inorganic filler is not particularly limited and may be a fibrous form, a flat plate form or a particulate form (including a spherical form). From the viewpoint of the mechanical properties and the friction abrasion property, the fibrous form is preferred. In applications in which a molded product is required to have an isotropic property, the flat plate form inorganic filler or the particulate inorganic filler is preferred. The size of the inorganic filler is not particularly limited. Any size of the inorganic filler such as nano size, micrometer size or millimeter size may be used depending on applications of a molded product.

Two or more type of the inorganic filler may be used in combination. Particularly, it is preferred to use the fibrous inorganic filler and the particulate inorganic filler or the plate form inorganic filler in combination.

Although the fiber length of the fibrous inorganic filler is not particularly limited, it is preferably at least 0.5 μm and at most 10 mm. Further, continuous fiber of which the fiber length is substantially infinite is preferred. For example, the fiber length of the fibrous inorganic filler may be from 0.5 to 10 μm, may be from 10 to 1,000 μm or may be from 1 to 10 mm. When the fiber length of the fibrous inorganic filler is at least the lower limit value, the heat resistance of a molded product will be further excellent. Further, the mechanical properties and the friction abrasion property of a molded product will be improved. When the fiber length of the fibrous inorganic filler is at most the upper limit value, the flowability at the time of molding may be easily obtained.

The diameter of the fibrous inorganic filler is not particularly limited and is preferably at least 0.001 μm and at most 30 μm. For example, the diameter of the fibrous inorganic filler may be from 0.001 to 1 μm, may be from 1 to 5 μm or may be from 5 to 30 μm.

When the diameter of the fibrous inorganic filler is at least the lower limit value, the heat resistance of a molded product will be further excellent. Further, the mechanical properties and the friction abrasion property of a molded product will be improved. When the diameter of the fibrous inorganic filler is at most the upper limit value, the dispersion property of the fibrous inorganic filler will be improved.

Although the average particle size of the particulate inorganic filler is not particularly limited, it is preferably at least 0.5 μm and at most 10 mm. The average particle size of the particulate inorganic filler may, for example, be from 0.5 μm to 10 μm, may be from 10 μm to 1,000 μm or may be from 1 mm to 10 mm. When the average particle size of the particular inorganic filler is at least the lower limit value, the heat resistance of a molded product will be further excellent. Further, the mechanical properties and the friction abrasion property of a molded product will be improved. When the average particle size of the particulate inorganic filler is at most the upper limit value, the flowability at the time of molding will be easily obtained.

Although the thickness of the flat plate inorganic filler is not particularly limited, it is preferably at least 1 nm and at most 100 μm. The thickness of the flat plate inorganic filler may, for example, be from 1 nm to 10 nm, may be from 10 nm to 1 μm or may be from 1 μm to 100 μm. When the thickness of the flat plate inorganic filler is at least the lower limit value, the heat resistance of a molded product will be further excellent.

Further, the mechanical properties and the friction abrasion property of a molded product will be improved. When the thickness of the flat plate inorganic filler is at most the upper limit value, the flowability at the time of molding will be easily obtained.

Although the long diameter of the flat plate inorganic filler is not particularly limited, it is preferably at least 0.5 μm and at most 100 μm. The long diameter of the flat plate inorganic filler may, for example, be from 0.5 μm to 10 μm, may be from 10 μm to 100 μm or may be from 100 μm to 1,000 μm. When the long diameter of the flat plate inorganic filler is at least the lower limit value, the heat resistance of a molded product will be further excellent. Further, the mechanical properties and the friction abrasion property of a molded product will be improved. When the long diameter of the flat plate inorganic filler is at most the upper limit value, the flowability at the time of molding will be easily obtained.

The inorganic filler may, for example, be carbon fiber, graphite, graphene, carbon nanotube, glass fiber, gypsum fiber, mica, talc, glass flake, wollastonite, potassium titanate, aluminum borate, boron nitride, aluminum nitride, calcium carbonate, silicon oxide (silica), titanium oxide, barium sulfate, zinc oxide, aluminum hydroxide, magnesium hydroxide, clay, carbon black, inorganic pigment, molybdenum disulfide, a metal powder, a magnetic material or zeolite.

Among them, from the viewpoint that the heat resistance of a molded product will be further excellent, carbon fiber, graphite, carbon nanotube or glass fiber is preferred, glass fiber or carbon fiber is more preferred, and from the viewpoint that the lightness of a molded product will be excellent, glass fiber is particularly preferred.

As the glass fiber, chopped fiber, milled fiber or flat glass fiber having a modified cross-section may be mentioned. Further, from the viewpoint of an electric property, glass fiber having a low dielectric constant may be used.

As the carbon fiber, PAN based carbon fiber, isotropic pitch-based carbon fiber or anisotropic pitch-based carbon fiber may be mentioned. As the shape of the carbon fiber, chopped fiber or milled fiber may be selected depending on the desired physical properties.

It is preferred to use the fibrous inorganic filler such as glass fiber or carbon fiber with another inorganic filler in combination. As another inorganic filler, a particulate inorganic filler or a flat plate inorganic filler may be mentioned. Such another inorganic filler may be one smaller than the above mentioned preferred size (for example, a nano size inorganic filler). As another inorganic filler, carbon black or silica may be mentioned. As a specific example of a combination of the fibrous inorganic filler and another inorganic filler, a combination of glass fiber and silica or a combination of carbon fiber and carbon black may be mentioned.

The carbon black may be one used as a filler for a fluorinated rubber. For example, furnace black, acetylene black, thermal black or channel black may be mentioned. Among them, furnace black is preferred. As the furnace black, HAF-LS carbon, HAF carbon, HAF-HS carbon, FEF carbon, GPF carbon, APF carbon, SRF-LM carbon, SRF-HM carbon, MT carbon or the like may be mentioned, and MT carbon is preferred.

In a case where the resin composition contains carbon black and another filler, the content of carbon black is preferably from 1 to 45 mass %, more preferably from 3 to 20%, to the resin composition. When the content of carbon black is at least the lower limit value in the above range, the strength of a molded product will be improved, and an effect by incorporating carbon black will be sufficiently obtained. When the content of carbon black is at most the upper limit value in the above range, elongation of a molded product will be excellent. When the content of carbon black is within the above range, the balance between the strength and elongation of a molded product will be good.

### (Other Components)

As other components, additives such as a polymer filler, a plasticizer, a flame retardant, etc. may be mentioned.

Two or more types of other components may be used in combination.

The polymer filler may be a liquid crystal polymer, a polycarbonate, a polyethylene terephthalate, a polybutylene terephthalate, a polyester elastomer, a polyarylate, a polycaprolactone, a phenoxy resin, a polysulfone, a polyether sulfone, a polyimide, a polyether imide, a polyamide 6, a polyamide 66, a polyamide 11, a polyamide 12, a polyamide 610, a polyamide 46, an aromatic polyamide, a polyamide elastomer, a polyphenylene oxide, a polyphenylene sulfide, a polytetrafluoroethylene, an acrylonitrile-butadiene-styrene copolymer (ABS resin), a polymethyl methacrylate, a polypropylene, a polyethylene, a polybutadiene, a butadiene-styrene copolymer, an ethyl-propylene-diene rubber (EPDM), a styrene-butadiene block copolymer, a butadiene-acrylonitrile copolymer, an acrylic rubber, a styrene-maleic acid anhydride copolymer, a styrene-phenylmaleimide copolymer, an ethylene-acrylic acid-glycidyl methacrylate copolymer, a silicon elastomer, aramide or the like.

Among them, a polytetrafluoroethylene is preferably used for further lowering the dielectric constant and the dielectric loss tangent of a molded product. In a case where the resin composition contains a polytetrafluoroethylene, the content of the polytetrafluoroethylene is preferably from 3 to 30 mass %, more preferably from 5 to 20 mass %, to 100 mass % of the resin composition of the present invention. When the polytetrafluoroethylene is at most the upper limit value, the strength of a molded product will be further excellent. When the polytetrafluoroethylene is at least the lower limit value, the effect of further improving the dielectric properties will be obtained.

The plasticizer may be a phthalic acid ester, an adipic acid ester, etc.

The flame retardant may be aluminum hydroxide, magnesium hydroxide, magnesium carbonate, antimony trioxide, sodium antimonate, antimony pentoxide, a phosphazene compound, a phosphoric acid ester (triphenyl phosphate, tricresyl phosphate, trixylenyl phosphate, cresylphenyl phosphate, 2-ethylhexyl diphenyl phosphate, etc.), ammonium polyphosphate, melamine/melam/melem polyphosphate, red phosphorus, a molybdenum compound, a boric acid compound, a polytetrafluoroethylene, etc.

As other components, a ultraviolet absorber, a light stabilizer, etc. may be further mentioned. The ultraviolet absorber may be a triazine-based ultraviolet absorber, a hydroxyphenyl triazine-based absorber, a benzophenone-based ultraviolet absorber or a benzotriazole-based ultraviolet absorber. Particularly, a benzotriazole-based ultraviolet absorber is preferred. As the light stabilizer, a hindered amine-based light stabilizer is preferred.

The content of the ultraviolet absorber and the content of the light stabilizer are preferably from 0.01 to 10.0 mass %, more preferably from 0.1 to 5.0 mass % respectively to 100 mass % of the resin composition of the present invention.

### (Method for Producing Resin Composition)

The resin composition is produced by melt-kneading the polyaryl ether ketone, the fluorinated elastomer, the inorganic filler and, as the case requires, other components.

The inorganic filler may be added at the time of melt-kneading the polyaryl ether ketone and the fluorinated elastomer, or may be added after melt-kneading the polyaryl ether ketone and the fluorinated elastomer.

In a case where other components are to be included in the resin composition, such other components may be added at the time of melt-kneading the polyaryl ether ketone and the fluorinated elastomer, or may be added after melt-kneading the polyaryl ether ketone and the fluorinated elastomer.

The fluorinated elastomer before melt-kneading is preferably crumb-shaped from the viewpoint of handling efficiency during compound preparation.

The number average particle diameter of the fluorinated elastomer before melt-kneading is preferably at most 10 mm, more preferably at most 8 mm, further preferably at most 6 mm. When the number average particle diameter of the fluorinated elastomer before melt-kneading is within the above range, the transportability by a screw during melt-kneading will be stabilized.

The volume ratio of the polyaryl ether ketone to the fluorinated elastomer in the melt-kneading is the same as the volume ratio of the polyaryl ether ketone to the fluorinated elastomer in the resin composition. When the proportion of the volume of the polyaryl ether ketone and the proportion of the volume of the fluorinated elastomer are within the above-mentioned ranges, the heat resistance, the flexural modulus and the impact resistance of a molded product to be formed will be improved.

The melt-kneading device may be a known device having a melt-kneading function. The melt-kneading device is preferably a single-screw extruder or a twin-screw extruder which may be provided with a screw having a high kneading effect, more preferably a twin-screw extruder, particularly preferably a twin-screw extruder provided with a screw having a high kneading effect. As the screw having a high kneading effect, it is possible to select one having a sufficient kneading effect with respect to an object to be melt-kneaded and not giving an excessive shearing force. As such a melt-kneading device, Labo Plastomill kneader (manufactured by Toyo Seiki Seisaku-sho, Ltd.) and KZW series twin screw extruder (manufactured by TECHNOVEL CORPORATION) may be mentioned.

As a method for supplying the polyaryl ether ketone and the fluorinated elastomer to the melt-kneading device, the polyaryl ether ketone and the fluorinated elastomer may be mixed in advance and supplied to the melt-kneading device, or the polyaryl ether ketone and the fluorinated elastomer may be separately supplied to the melt-kneading device.

As a method for supplying the inorganic filler to the melt-kneading device, the inorganic filer is preferably added after melt-kneading the polyaryl ether ketone and the fluorinated elastomer. The inorganic filler may be mixed to the polyaryl ether ketone and the fluorinated elastomer in advance and then supplied to the melt-kneading device.

In a case where other components are to be included in the resin composition, such other components may be mixed in advance with one of the polyaryl ether ketone and the fluorinated elastomer and supplied to the melt-kneading device, or they may be supplied to the melt-kneading device separately from the polyaryl ether ketone and the fluorinated elastomer. Further, other components may be added after melt-kneading the polyaryl ether ketone and the fluorinated elastomer.

The temperature when melt-kneading the polyaryl ether ketone and the fluorinated elastomer (hereinafter also referred to as “melt-kneading temperature”) is preferably set depending on the polyaryl ether ketone and the fluorinated elastomer. The melt-kneading temperature is preferably from 220 to 480° C., more preferably from 280 to 450° C., further preferably from 290 to 420° C., particularly preferably from 300 to 400° C.

The extrusion shear rate when melt-kneading the polyaryl ether ketone and the fluorinated elastomer is preferably set depending on the melt viscosity of the object to be melt-kneaded comprising the polyaryl ether ketone and the fluorinated elastomer at the melt-kneading temperature. The extrusion shear rate in the melt-kneading is preferably from 3 to 2,500 sec⁻¹, more preferably from 10 to 2,000 sec⁻¹, further preferably from 15 to 1,500 sec⁻¹.

The residence time of the object to be melt-kneaded in the melt-kneading device is preferably from 10 to 290 seconds, more preferably from 20 to 240 seconds, further preferably from 30 to 210 seconds.

The melt-kneading the polyaryl ether ketone and the fluorinated elastomer is preferably carried out so that particles of the fluorinated elastomer having a number average particle diameter of from 0.5 to 10 μm will be dispersed in the polyaryl ether ketone. By suitably adjusting the melt-kneading temperature, the extrusion shear rate and the residence time of the object to be melt-kneaded in the melt-kneading device, it is possible to disperse the particles of the fluorinated elastomer having a number average particle diameter of from 0.5 to 10 μm in the polyaryl ether ketone.

By increasing the melt-kneading temperature, the fluorinated elastomer will be easily dispersed in the polyaryl ether ketone, and coarse particles of the fluorinated elastomer will be less likely to remain. By lowering the melt-kneading temperature, thermal decomposition of the fluorinated elastomer will be less likely to be promoted, the heat resistance of the resin composition will be further excellent, and the fluorinated elastomer will not be made too small in particle size.

By increasing the extrusion shear rate, the fluorinated elastomer tends to be easily dispersed in the polyaryl ether ketone, and coarse particles of the fluorinated elastomer will be less likely to remain. By reducing the extrusion shear rate, the fluorinated elastomer will not be made too small in particle size.

When the residence time of the object to be melt-kneaded in the melt-kneading device is prolonged, the fluorinated elastomer tends to be easily dispersed in the polyaryl ether ketone, and coarse particles of the fluorinated elastomer will be less likely to remain. When the residence time is shortened, the thermal decomposition of the fluorinated elastomer will be less likely to be promoted.

The melt-kneading is preferably carried out in the substantial absence of a crosslinking agent and a crosslinking aid. The melt-kneading being carried out in the substantial absence of a crosslinking agent and a crosslinking aid, means that melt-kneading is carried out while the fluorinated elastomer in the resin composition is not substantially cross-linked. Whether or not the fluorinated elastomer in the resin composition is not substantially crosslinked, can be confirmed by the value of the flexural modulus of the resin composition.

A resin composition obtained by melt-kneading the object to be melt-kneaded containing the polyaryl ether ketone and the fluorinated elastomer, is melt-moldable and thus is useful as a material for a molded product.

The resin composition of the present invention may be powdered and used as a coating material. Applications of the coated articles may be applications as described in WO2015/182702.

### (Function and Mechanism)

According to the above described resin composition of the present invention, a molded product which has the deflection temperature T₀ under load higher than the deflection temperature T₁ under load of the comparative composition (1) and which is excellent in the heat resistance will be obtained.

Further, the proportion of the volume of the fluorinated elastomer to the total of the volume of the polyaryl ether ketone and the volume of the fluorinated elastomer is at least 5 vol %, and the amount of the fluorinated elastomer is thereby sufficient. Thus, the impact resistance of a molded product will be sufficiently obtained.

Further, the proportion of the volume of the fluorinated elastomer to the total of the volume of the polyaryl ether ketone and the volume of the fluorinated elastomer is at most 45 vol %, and the amount of the polyaryl ether ketone is thereby sufficient. Thus, the flexural modulus and the heat resistance of a molded product will be sufficiently obtained.

Further, the resin composition of the present invention contains at least 1 mass % of the inorganic filler to the composition, in addition to the polyaryl ether ketone and the fluorinated elastomer. Therefore, as shown in the after described Examples, synergistic effects by functions of three components of the polyaryl ether ketone, the fluorinated elastomer and the inorganic filler can be obtained. As a result, the flexural modulus, the heat resistance and the impact resistance at a low temperature of a molded product are improved beyond standard expectations of those skilled in the art. The reason why the synergistic effects can be obtained is not clear, however, the influence of crystallization of the polyaryl ether ketone is considered.

Consequently, according to the resin composition of the present invention, a molded product which has a high flexural modulus and which is excellent in the heat resistance and the impact resistance at a low temperature can be obtained.

### <Molded Product>

The molded product of the present invention is a molded product of the resin composition of the present invention. The shape of the molded product of the present invention is optionally selected depending on the form, applications, etc. of the molded product.

Since the flexural modulus is high, and the heat resistance and the impact resistance at low temperature are excellent, the molded product of the present invention is preferably used in applications in which such properties are required.

In a case where the resin composition of the present invention contains for example, glass fiber and silica as the inorganic filler, the molded product has a high lightness and is thereby preferably used in applications in which the outer appearance is important. Since the polyaryl ether ketone is originally dark brown, the polyaryl ether ketone is usually whitened with a white pigment or the like or colored to a color other than dark brown for use. However, the use of a pigment or the like for such coloration may sometimes impair the excellent physical properties of the polyaryl ether ketone.

In a case where the resin composition of the present invention contains, for example, glass fiber and silica as the inorganic filler, the molded product has a high value of L* in the hue measurement in accordance with JIS-Z8781-4 and thereby has a high lightness. Accordingly, it is not necessary to carry out treatment for whitening or coloration, and the excellent physical properties of the polyaryl ether ketone are less likely to be impaired. Thus, there is an advantage that the molded product can be preferably used for a mobile electronic device of which the outer appearance is important.

The form and the application of the molded product of the present invention may be a housing of a mobile electronic device, a connecting member for a mobile electronic device, a sliding member, a three-dimensional electronic circuit component, a gear, an actuator, a piston, a bearing, an aircraft interior material, a bush, a tube (for fuel, etc.), a hose, a tank, a seal, a wire, an insulating coating material for an electric wire (a wire, a cable, etc.), a film, a sheet, a bottle, a fiber, etc.

Since a mobile electronic device is used in hand, oil contained in food products and cosmetics and liquid such as beverage, sweat and sebum tend to attach. The molded product of the present invention is less likely to be colored due to such attachments and less likely to deteriorate, whereby the molded product of the present invention can be preferably used in applications of the mobile electronic device.

The mobile electronic device may, for example, be a cellphone, a mobile terminal, a laptop computer, a tablet computer, a radio, a camera, an accessory for a camera, a watch, a calculator, a music player, GPS, a portable game, a hard drive, a mobile memory device, a mobile reproducing device or a mobile radio receiver.

The form of the hosing of the mobile electronic device may, for example, be a back cover of the mobile electronic device, a front cover, an antenna housing, a frame or a backbone. The housing may be a member consisting of only one component of the molded product of the present invention or may be a member comprising plural components. Here, the backbone is a member to which a component of the mobile electronic device such as electronics, microprocessor, a screen, a keyboard, a keypad, an antenna or a battery socket is fixed.

In a case where the housing is in the inside of the mobile electronic device, the housing cannot be viewed from the outside of the mobile electronic device in some cases and can be partially viewed from the outside of the mobile electronic device in the other cases. The housing such as a cover for protecting or supporting an internal structure may be exposed to the outside of the mobile electronic device.

The form of a connecting member for the mobile electronic device may be a snap connector to a circuit board, a microphone, a speaker, a display, a battery, a cover, an electronic connector, an electronic connector, a hinge, an antenna, a switch, a switch pad for the mobile electronic device, etc. The connecting member can be preferably used for mobile electronic devices such as a cellphone, a PDA, a music memory device, a bugging device, a mobile DVD player, an electric multimeter, a mobile electronic game device and a mobile personal computer (such as a notebook computer).

The three-dimensional electronic circuit component is a resin component molded into a three-dimensional shape and having a circuit pattern formed on its surface and is used as an antenna component for a mobile electronic device or a component for an onboard electronic apparatus. As the method for forming a circuit pattern, a laser direct structuring (LDS) method of etching a circuit pattern by laser, followed by plating, is used. The molded product of the present invention is excellent in the low dielectric properties and preferably used for a three-dimensional electronic circuit component.

Applications of the tube, hose, tank, seal and wire may be the applications as described in WO2015/182702. In addition, applications of the tube and hose may be tubes for energy resource drilling for oil, natural gas, shale oil, etc. Among them, the tube for oil drilling is preferred.

The application of the insulating coating material for electric wires may be an insulating coating material for an electric wire for a motor coil or for a rectangular copper wire, particularly for a rectangular conductor in a drive motor of a hybrid vehicle (HEV) or an electric vehicle (EV). As the form of the insulating coating material for the rectangular conductor, a film is preferred. Further, as the application of the insulating coating material for electric wires, an insulating coating material for downhole cables for energy resource (oil, natural gas, shale oil, etc.) drilling may be mentioned. Among them, the insulating coating material for downhole cables for oil drilling is preferred.

The application of the film and sheet may be a speaker diaphragm, a plate for external damage/fractures, an insulating paper such as an adhesive tape for various electrical insulation (motor insulating paper, etc.), a sealing tape for oil/natural gas pipes, etc., or a release film at the time of molding thermosetting or thermoplastic composite materials.

In a case where the molded product is a film, its application is preferably a speaker diaphragm provided with a film, a film for coating electric wire, a flexible printed board, a heat-resistant roll for an OA equipment or a film for film impregnation of another fiber composite material.

The thickness of the film is preferably from 1 to 100 μm, more preferably from 2 to 80 μm, further preferably from 5 to 50 μm. When the thickness of the film is at least the lower limit value in the above range, the strength of the film is improved. When the thickness of the film is at most the upper limit value in the above range, the film will be excellent in handling efficiency in a subsequent step.

In a case where the molded product is a tube, its application is preferably a medical catheter equipped with a tube, a wire coating or piping for an analytical instrument.

In a case where an extruded product is a fiber, its application is preferably protective clothing or various filters.

The molding method may be an injection molding method, an extrusion method, a coextrusion method, a blow molding method, a compression molding method, a transfer molding method, a calendering method, etc.

In a case where the molded product is a film, the molding method may be an extrusion method such as a T-die method or a blown-film extrusion method. In the T-die method, the flow rate of the molten resin and the thickness of the film can be precisely controlled by adjusting the choke bar and lip in the T-die. In the blown-film extrusion method, by introducing air from a circular die into the extruded product and expanding it to obtain a film, the thickness of the film can be made uniform.

In a case where the molded product is a fiber, as the molding method, an extrusion method such as a melt-spinning method is preferred.

### <Composite>

The composite of the present invention comprises the molded product of the present invention combined or laminated with another material. Another material may be a metal, glass, plastic, rubber, etc.

Specific examples of the plastic include those described in WO2015/182702, liquid crystal polymers, polyaryl ketones, polyether sulfones, polyphenyl sulfones, polyacetals, polyurethanes, etc. Polyamides include a polyamide 6, a polyamide 66, a polyamide 46, a polyamide 11, a polyamide 12, a polyamide 610, a polyamide 612, a polyamide 6/66 copolymer, a polyamide 6/66/610 copolymer, a polyamide MXD6, a polyamide 6T, a polyamide 9T, a polyamide 6/6T copolymer, etc.

Among them, as another material, a metal and glass are preferred. The metal is preferably iron, copper, stainless steel, steel, aluminum, magnesium, titanium or the like.

The composite of the present invention is a composite comprising the molded product excellent in the chemical resistance, with another material whereby the composite of the present invention can be preferably used in applications for a material to be treated with a strong chemical in a production step. For example, as in a mobile electronic device in which a composite of a resin with a metal, glass or the like is widely used, a composite of the molded product of the present invention with another material such as metal or glass can be preferably used for a mobile electronic device.

A composite of a resin with a metal (such as aluminum or stainless steel) to be used for a mobile electronic device, etc. is usually subjected to anodic oxidation for improving the surface hardness or the outer appearance. The anodic oxidation is treatment of forming an oxide layer on a metal surface with a strong chemical to improve the surface hardness. Therefore, a composite of a resin with a metal to be subjected to anodic oxidation, particularly, the resin part, is required to have excellent chemical resistance. The composite of the present invention can be preferably used for a mobile electronic device of which the outer appearance is important, since the composite of the present invention is easily applicable to anodic oxidation.

In a case of the composite of the molded product of the present invention with a metal, the metal part shields electromagnetic waves, and radio signal passes through the part of the molded product of the present invention. The composite of the molded product of the present invention with a metal is preferably used for a mobile electronic device from the viewpoint of the low dielectric properties, since the molded product of the present invention is excellent in the low dielectric properties.

The composite of the present invention may, for example, be produced by bonding the molded product and another material. The bonding method is not particularly limited, and various methods may be employed.

For example, a method of bonding the molded product of the present invention to another material such as a metal to which an adhesive is applied; and a method of injecting the molten resin composition of the present invention to a metal member put in a metal mold in the injection molding, may be mentioned.

In the case of forming the composite with a metal by the injection molding, the molded product of the present invention can be combined with a metal member as it is, however, the injection molding may be carried out after conducting chemical adhesive treatment on a surface of the metal member, or after conducting physical or chemical treatment for forming unevenness on the surface of the metal member.

As the chemical adhesive treatment, a metal member coated with an adhesive may be used. As the method for forming unevenness by physical treatment, for example, laser processing or mechanical processing may be mentioned. As the method for forming unevenness by chemical treatment, for example, chemical etching may be mentioned.

The composite of the molded product and a metal, which is produced by the injection molding may be formed into the desired shape by mechanical processing or cut processing.

### EXAMPLES

In the following, the present invention will be described in detail with reference to Examples, but the present invention is not limited thereto.

Ex. 1 to 4, 7 to 10 and Ex. 14 to 18 are Examples of the present invention, and Ex. 5, 6 and 11 to 13 are Comparative Examples.

### (Preparation of Injection-Molded Product for Evaluation)

Using an injection molding machine (ROBOSHOT α-50, manufactured by FANUC CORPORATION), the resin composition was injection-molded at a cylinder temperature of 380° C. and a mold temperature of 170° C., to obtain an injection-molded product having a thickness of 4.0 mm for evaluation.

### (Flexural Modulus and Flexural Strength)

A test piece having a length of 80 mm and a width of 10 mm was cut out from the injection-molded product for evaluation. With respect to the test piece, using TENSILON (RTF-1350, manufactured by A&D Company, Limited), the flexural modulus and the flexural strength were measured at load cell rate of 10 at a distance between fulcrums of 64 mm at a speed of 2 mm/min in accordance with JIS K7171.

### (Tensile Strength and Tensile Elongation)

With respect to the injection-molded product for evaluation, the tensile strength and the tensile elongation were measured by using TENSILON (RTF-1350, manufactured by A&D Company, Limited) at a load cell rate of 10 kN, at a chuck distance of 115 mm at a rate of 50 mm/min in accordance with JIS K7161.

### (Izod Impact Strength)

From the injection-molded product for evaluation, a test piece having a length of 80 mm and a width of 10 mm was cut out, and a notch was imparted at a height of 40 mm of the test piece.

With respect to the test piece, using an Izod tester (manufactured by Toyo Seiki Seisaku-sho, Ltd.), the Izod impact strength was measured under conditions of a hammer capacity of 2.75J, a hammer load of 13.97N, a distance from the shaft center to the center of gravity being 10.54 cm, a distance from the shaft center to the striking point being 33.5 cm. The measurements were carried out at 23° C. and −40° C.

### (Deflection Temperature Under Load)

From the injection-molded product for evaluation, a test piece having a length of 80 mm and a width of 10 mm was cut out. In accordance with ASTM D648, using HDT & VSPT TESTER manufactured by Toyo Seiki Seisaku-sho, Ltd., the temperature at which a deflection amount reached 0.254 mm, was measured under conditions of a load of 1.82 MPa and a heating rate of 2° C./min.

### (Dielectric Constant)

Using a melt heat press machine, the resin composition was press-molded to obtain a press sheet having a thickness of 0.24 mm. Referring to ASTM D2520, using a PNA-L network analyzer (N5230A, manufactured by Agilent Technologies) and a cavity resonator (CP481, manufactured by Kanto Electronics Application Development Co., Ltd.), the dielectric constant of the press sheet was measured under conditions of a temperature of 23° C., a humidity of 50% RH and a frequency of 10 GHz.

### (Dynamic Friction Coefficient)

A test was carried out by using a friction abrasion tester FRT IIEAA, manufactured by T.S.E Co., Ltd. by MATSUBARA friction measuring method (cylindrical type, ring on ring) in accordance with JIS K-7218.

At room temperature, a cylindrical test piece produced from the resin composition by the injection molding was brought into contact with a ring (material: SUS316, contacting surface: 2 cm²) of an opposite material under conditions of a pressure of 0.4 MPa, a rotational rate of 0.5 m/sec and test time of 1 hour to measure a dynamic friction constant of the test piece.

### (Hue Measurement)

With regard to the injection-molded product for evaluation, the hue measurement was carried out by using an SM color computer SM-T manufactured by Suga Test Instruments Co., Ltd. in accordance with JIS-Z8781-4 to measure L*, a* and b*.

### (Chemical Resistance)

With regard to the respective injection-molded products for evaluation immersed in a 70% sulfuric acid solution, at 23° C. for 24 hours and 168 hours respectively, the tensile strength and the tensile elongation were measured.

### (Raw Material)

Polyaryl ether ketone (A-1): PEEK (melting point: 340° C., melt flow rate: 22 g/10 min, specific gravity: 1.32, Vestakeep 3300G, manufactured by Daicel-Evonik Ltd.)

Fluorinated elastomer (B-1): Tetrafluoroethylene-propylene copolymer (melt flow rate: 11 g/10 min, specific gravity: 1.55, Moony viscosity (ML₁₊₁₀, 121° C.): 100, storage elastic modulus G′ (100° C., 50 cpm): 390, AFLAS (registered trademark) 150 FC, manufactured by AGC Inc.)

Inorganic filler (C-1): Glass fiber (NE glass CN 3DE-451, manufactured by NITTO BOSEKI CO., LTD.)

Inorganic filler (C-2): Glass fiber (NE glass CN 3DE-941, manufactured by NITTO BOSEKI CO., LTD.)

Inorganic filler (C-3): Carbon fiber (PXCA0250-83, manufactured by ZOLTEK)

Polymer filler (D-1): Polytetrafluoroethylene (L169J, manufactured by AGC Inc.)

Polymer filler (D-2): Polytetrafluoroethylene (L170JE, manufactured by AGC Inc.)

Ultraviolet absorber (E-1): Hydroxyphenyl triazine (HPT) type ultraviolet absorber (Tinuvin 479 manufactured by BASF)

Light stabilizer (E-2): Hindered amine light stabilizer (HALS) (Tinuvin PA144 manufactured by BASF)

### Ex. 1 to 4 and 7 to 10

Polyaryl ether ketone (A-1), fluorinated elastomer (B-1) and inorganic filler (C-1), inorganic filler (C-2) or inorganic filler (C-3), and polymer filler (D-1) were mixed in a blend ratio as shown in Table 1 or 2 and added to the base end of the screw of a twin-screw extruder (KZW15TW-45HG1100, manufactured by Technovel Corporation, screw diameter: 15 mmϕ, L/D: 45) at a rate of 2.0 kg/hour by using a feeder. The strand extruded from the die tip under the conditions of screw rotation speed: 200 rpm, set temperatures of cylinder, die and head: C1=340° C., C2=350° C., C3=360° C., C4=370° C., C5=370° C., C6=370° C., D=350° C., H=350° C., was cooled in a water tank and cut by a pelletizer to obtain pellets of the resin composition.

In the blend ratios shown in Tables 1 and 2, “volume ratio (vol %)” is each of proportions of the volume of the polyaryl ether ketone (A-1) and the volume of the fluorinated elastomer (B-1), to their total. Further, “proportion (mass %) of inorganic filler” and “proportion (mass %) of polymer filler” are the proportions of each inorganic filler and each polymer filler to 100 mass % of the resin composition. The same applies to the other examples described below.

### Ex. 5 and 11

Pellets of the resin compositions were obtained in the same manner as in Ex. 1, except that without using the inorganic filler, polyaryl ether ketone (A-1) and fluorinated elastomer (B-1) were mixed in the blend ratio shown in Tables 1 and 2. Here, the composition in Ex. 5 is a comparative composition (1) for the resin compositions in Ex. 1-4 and 7. Further, the composition in Ex. 11 is a comparative composition (1) for the resin compositions in Ex. 8-10.

### Ex. 6

Pellets of a resin composition were obtained in the same manner as in Ex. 1, except that only polyaryl ether ketone (A-1) was used without using the fluorinated elastomer and the inorganic filler.

### Ex. 12 and 13

Pellets of resin compositions were obtained in the same manner as in Ex. 1, except that without using the fluorinated elastomer, polyaryl ether ketone (A-1) and inorganic filler (C-1) or inorganic filler (C-2) were mixed in the blend ratio shown in Table 2. Here, the composition in Ex. 12 is a comparative composition (2) for the resin compositions in Ex. 1 and 8. Further, the resin composition in Ex. 13 is a comparative composition (2) for the resin compositions in Ex. 2, 7 and 9.

### Ex. 14 to 18

Pellets were produced in the same manner as in Ex. 10, except that the blend ratios were as shown in Table.

The formulated compositions in Ex. 1 to 18 and physical properties of the obtained resin compositions are shown in the following Tables 1 to 3.

TABLE 1

| | | | Ex. 1 | Ex. 2 | Ex. 3 | Ex. 4 | Ex. 5 | Ex. 6 | Ex. 7 |
|---|---|---|---|---|---|---|---|---|---|
| Blend | Volume ratio (vol %) | Polyaryl ether ketone (A-1) | 80 | 80 | 80 | 80 | 80 | 100 | 80 |
| ratio | | Fluorinated elastomer (B-1) | 20 | 20 | 20 | 20 | 20 | — | 20 |
| | Proportion of inorganic filler | Inorganic filler (C-1) | 20 | — | — | — | — | — | — |
| | (mass %) | Inorganic filler (C-2) | — | 20 | 30 | — | — | — | 20 |
| | | Inorganic filler (C-3) | — | — | — | 20 | — | — | — |
| | Proportion of other | Polymer filler (D-1) | — | — | — | — | — | — | 10 |
| | components (mass %) | | | | | | | | |

| | | | | | | | | |
|---|---|---|---|---|---|---|---|---|
| Physical | Flexural modulus (GPa) | 7.6 | 7.0 | 8.6 | 11.0 | 3 | 3.6 | 6.3 |
| property | Flexural strength (MPa) | 190.0 | 190.0 | 195 | 190.0 | 100 | 152 | 149 |
| | Tensile strength (MPa) | 117.0 | 117.0 | 134 | 119.0 | 70 | 85 | 95 |
| | Izod impact strength (J/cm) 23° C. | 1.04 | 1.06 | 0.74 | 0.79 | 0.61 | 0.38 | 0.97 |
| | Izod impact strength (J/cm) −40° C. | 1.06 | 1.08 | 0.88 | 0.72 | 0.37 | 0.34 | 0.89 |
| | Deflection temperature under load (° C.) | 290 | 290 | 290 | 290 | 152 | 155 | 280 |
| | Difference in deflection temperature under load from | 138 | 138 | 138 | 138 | 0 | 3 | 128 |
| | comparative composition 1 | | | | | | | |
| | Difference in deflection temperature under load from Ex. 6 | 135 | 135 | 135 | 135 | −3 | 0 | 125 |
| | Dielectric constant (10 GHz) | 3.2 | 3.3 | 3.3 | — | 2.9 | — | 2.9 |
| | Dynamic friction constant | 0.3 | 0.28 | 0.3 | 0.31 | 0.5 | — | — |
| Physical | Hue L* | 84.7 | 85 | 84 | — | — | — | — |
| property | Hue a* | −0.09 | −0.09 | −0.09 | — | — | — | — |
| | Hue b* | 8.7 | 8.8 | 8.8 | — | — | — | — |
| | Chemical resistance | 115 | 116 | — | — | — | — | — |
| | (tensile strength (MPa) after immersion for 24 hours) | | | | | | | |
| | Chemical resistance | 4 | 5 | — | — | — | — | — |
| | (tensile elongation (%) after immersion for 24 hours) | | | | | | | |
| | Chemical resistance | 116 | 117 | — | — | — | — | — |
| | (tensile strength (MPa) after immersion for 168 hours) | | | | | | | |
| | Chemical resistance | 4 | 4 | — | — | — | — | — |
| | (tensile elongation (%) after immersion for 168 hours) | | | | | | | |

TABLE 2

| | | | Ex. 8 | Ex. 9 | Ex. 10 | Ex. 11 | Ex. 12 | Ex. 13 |
|---|---|---|---|---|---|---|---|---|
| Blend | Volume ratio (vol %) | Polyaryl ether ketone (A-1) | 70 | 70 | 70 | 70 | 100 | 100 |
| ratio | | Fluorinated elastomer (B-1) | 30 | 30 | 30 | 30 | — | — |
| | Proportion of inorganic filler | Inorganic filler (C-1) | 20 | — | — | — | 20 | — |
| | (mass %) | Inorganic filler (C-2) | — | 20 | 30 | — | — | 20 |
| | | Inorganic filler (C-3) | — | — | — | — | — | — |

| | | | | | | | |
|---|---|---|---|---|---|---|---|
| Physical | Flexural modulus (GPa) | 5.9 | 6.4 | 8.3 | 2.6 | 6.6 | 6.4 |
| property | Flexural strength (MPa) | 120.0 | 160.0 | 177 | 75 | 215.0 | 209.0 |
| | Tensile strength (MPa) | 90 | 105.0 | 117 | 60 | 123.0 | 118.0 |
| | Izod impact strength (J/cm) 23° C. | 0.94 | 0.96 | 0.76 | 1.64 | 0.83 | 0.69 |
| | Izod impact strength (J/cm) −40° C. | 0.94 | 1.03 | 0.87 | 0.59 | 0.92 | 0.87 |
| | Deflection temperature under load (° C.) | 275 | 281 | 290 | 151 | 254 | 252 |
| | Difference in deflection temperature under load from | 124 | 130 | 139 | 0 | 103 | 101 |
| | comparative composition 1 | | | | | | |
| | Difference in deflection temperature under load from Ex. 6 | 120 | 126 | 135 | −4 | 99 | 97 |
| | Dielectric constant (10 GHz) | 3.1 | 3.1 | 3.1 | 2.86 | 3.4 | 3.4 |
| | Dynamic friction constant | 0.31 | 0.3 | 0.3 | 0.52 | 0.3 | 0.3 |
| Physical | Hue L* | 85.9 | 86.1 | 86 | — | 57.7 | 58.1 |
| property | Hue a* | −0.09 | −0.09 | −0.09 | — | −0.54 | −0.55 |
| | Hue b* | 8 | 8.2 | 8.1 | — | 12.8 | 12.5 |
| | Chemical resistance | 91 | 101 | — | — | — | — |
| | (tensile strength (MPa) after immersion for 24 hours) | | | | | | |
| | Chemical resistance | 4 | 4 | — | — | — | — |
| | (tensile elongation (%) after immersion for 24 hours) | | | | | | |
| | Chemical resistance | 89 | 104 | — | — | — | — |
| | (tensile strength (MPa) after immersion for 168 hours) | | | | | | |
| | Chemical resistance | 5 | 4 | — | — | — | — |
| | (tensile elongation (%) after immersion for 168 hours) | | | | | | |

TABLE 3

| | | | Ex. 14 | Ex. 15 | Ex. 16 | Ex. 17 | Ex. 18 |
|---|---|---|---|---|---|---|---|
| Blend | Volume ratio (vol %) | Polyaryl ether ketone (A-1) | 80 | 80 | 80 | 80 | 80 |
| ratio | | Fluorinated elastomer (B-1) | 20 | 20 | 20 | 20 | 20 |
| | Proportion of inorganic filler | Inorganic filler (C-1) | | | | | |
| | (mass %) | Inorganic filler (C-2) | 30 | 30 | 30 | 30 | 30 |
| | | Inorganic filler (C-3) | | | | | |
| | Proportion of other | Polymer filler (D-2) | | | | 15 | 30 |
| | components (mass %) | Ultraviolet absorber (E-1) | 0.5 | 1.0 | 0.5 | | |
| | | Light stabilizer (E-2) | | | 0.5 | | |

| | | | | | | |
|---|---|---|---|---|---|---|
| Physical | Hue L* | 82.1 | 82.8 | 79.2 | 84.3 | 83.5 |
| property | Hue a* | −0.3 | −0.2 | −0.3 | 0.22 | 0.33 |
| | Hue b* | 10.1 | 11.1 | 15.2 | 11 | 11.5 |

The deflection temperature under load of each of the resin compositions in Ex. 1 to 4 and 7 is higher than the deflection temperature under load of the composition in Ex. 5. The flexural modulus, the heat resistance and the impact resistance at low temperature of each of the resin compositions in Ex. 1 to 4 and 7 are superior to those of the composition in Ex. 5.

Further, the deflection temperature under load of each of the resin compositions in Ex. 8 to 10 is higher than the deflection temperature under load of the composition in Ex. 11. The flexural modulus, the heat resistance and the impact resistance at a low temperature of each of the resin compositions in Ex. 8 to 10 are superior to those of the composition in Ex. 11.

The heat resistance and the impact resistance in Ex. 1 and 8 in which inorganic filler (C-1) was used are superior to those in Ex. 12 in which the same inorganic filler (C-1) was used.

The heat resistance and the impact resistance in Ex. 2 and 9 in which inorganic filler (C-2) was used are superior to those in Ex. 13 in which the same inorganic filler (C-2) was used.

With regard to the heat resistance, according to standard knowledge of those skilled in the art, the heat resistance of the resin compositions containing fluorinated elastomer (B-1) in addition to polyaryl ether ketone (A-1) and inorganic filler (C-1) or (C-2) in Ex. 1, 2, 8 and 9, was inferior to that of the resin compositions comprising two components of polyaryl ether ketone (A-1) and inorganic filler (C-1) or (C-2) in Ex. 12 and 13.

However, the deflection temperature under load of the resin compositions in Ex. 1 and 8 was higher than the deflection temperature under load of the composition comprising two components of polyaryl ether ketone (A-1) and inorganic filler (C-1) in Ex. 12. Further, the deflection temperature under load of the resin compositions in Ex. 2 and 9 was also higher than the deflection temperature under load of the composition comprising two components of polyaryl ether ketone (A-1) and inorganic filler (C-2) in Ex. 13.

It is considered from these results that in the resin composition comprising a polyaryl ether ketone, a fluorinated elastomer and inorganic filler, the synergistic effects by the functions of these three components can be obtained, whereby the heat resistance of the molded product is improved beyond standard expectations of those skilled in the art.

Also with regard to the flexural modulus, according to standard knowledge of those skilled in the art, it is expected that the resin compositions in Ex. 1, 2 and 9 contain fluorinated elastomer (B-1) in addition to polyaryl ether ketone (A-1) and inorganic filler (C-1) or (C-2) and thereby have a flexural modulus lower than that of the resin compositions comprising two components of polyaryl ether ketone (A-1) and inorganic filler (C-1) or (C-2) in Ex. 12 and 13.

However, the flexural modulus of the resin composition in Ex. 1 was higher than that of the composition comprising two components of polyaryl ether ketone (A-1) and inorganic filler (C-1) in Ex. 12. Further, the flexural modulus of the resin compositions in Ex. 2 and 9 was the same as or higher than that of the composition comprising two components of polyaryl ether ketone (A-1) and inorganic filler (C-2) in Ex. 13.

It is considered from these results that according to the resin composition comprising the polyaryl ether ketone, the fluorinated elastomer and the inorganic filler, synergistic effects can be obtained by the functions of these three components, whereby the flexural modulus of the molded product is also improved beyond standard expectations of those skilled in the art.

With regard to the lightness, in Ex. 1, 2, 3, 8 to 10, the lightness L* was at least 80 in all cases, and the evaluation results were thereby good. Further, in Ex. 16, the lightness L* was at least 75, and the lightness L* in Ex. 14, 15, 17 and 18 was at least 80 in all cases, and the evaluation results were thereby good.

With regard to the chemical resistance, the values of the tensile strength and the tensile elongation in Ex. 1, 2, 8 and 9 are as shown in Tables 1 and 2, and the values before immersion in a 70% sulfuric acid solution were maintained. It is evident from the result that the chemical resistance is good.

With regard to the dielectric constant, the dielectric constant in Ex. 1 to 3 and Ex. 8 to 10 was lower than that in Ex. 12 and 13, and the dielectric constant in Ex. 7 was further low. It is evident from the result that the low dielectric property is good.

### INDUSTRIAL APPLICABILITY

The molded product of the resin composition of the present invention has a high flexural modulus and is excellent in the heat resistance and the impact resistance at a low temperature, and is thereby useful in applications in which such properties are required.

This application is a continuation of PCT Application No. PCT/JP2021/029662, filed on Aug. 11, 2021, which is based upon and claims the benefit of priority from Japanese Patent Application No. 2020-136980 filed on Aug. 14, 2020 and Japanese Patent Application No. 2020-204468 filed on Dec. 9, 2020. The contents of those applications are incorporated herein by reference in their entireties.

What is claimed is:

1. A resin composition comprising a polyaryl ether ketone, a fluorinated elastomer and an inorganic filler,
wherein the proportion of the volume of the fluorinated elastomer to the total of the volume of the polyaryl ether ketone and the volume of the fluorinated elastomer, is from 1 to 45 vol %,
the proportion of the mass of the inorganic filler to the resin composition is from 1 to 50 mass %, and
the deflection temperature under load measured in accordance with ASTM D648 under a load of 1.82 MPa is higher than the deflection temperature under load of the following comparative composition:
comparative composition: a resin composition comprising the above polyaryl ether ketone and the above fluorinated elastomer and not containing the above inorganic filler, wherein the type of the polyaryl ether ketone, the type of the fluorinated elastomer and the proportion of the volume of the fluorinated elastomer to the total of the volume of the polyaryl ether ketone and the volume of the fluorinated elastomer are the same as those of the above resin composition, except that the inorganic filler is not contained.

2. The resin composition according to claim 1, wherein the fluorinated elastomer is a copolymer having units based on tetrafluoroethylene and units based on propylene, a copolymer having units based on hexafluoropropylene and units based on vinylidene fluoride or a copolymer having units based on tetrafluoroethylene and units based on a compound represented by the following formula (1):
CF₂═CF(OR^{F}) (1)
where R^{F} is a C₁₋₈ linear or branched perfluoroalkyl group.

3. The resin composition according to claim 1, wherein the polyaryl ether ketone is a polyether ketone, a polyether ether ketone or a polyether ketone ketone.

4. The resin composition according to claim 1, wherein the lightness L* in the hue measurement in accordance with JIS-Z8781-4 is at least 60.

5. The resin composition according to claim 1, wherein the inorganic filler is a fibrous inorganic filler, a flat plate inorganic filler or a particulate inorganic filler.

6. The resin composition according to claim 1, which contains as the inorganic filler, at least one member selected from the group consisting of carbon fiber, graphite, carbon nanotube, glass fiber and silica.

7. The resin composition according to claim 1, which contains as at least a part of the inorganic filler, carbon fiber or glass fiber.

8. The resin composition according to claim 1, which further contains a polymer filler.

9. The resin composition according to claim 8, wherein the polymer filler is a polytetrafluoroethylene.

10. The resin composition according to claim 1, which further contains at least one member selected from the group consisting of a plasticizer, an ultraviolet absorber and a light stabilizer.

11. A molded product obtained by molding the resin composition as defined in claim 1.

12. A composite comprising the molded product as defined in claim 11 combined or laminated with another material.

13. A mobile electronic device, a sliding member, a three-dimensional electronic circuit component, an electric wire or a member for energy resource drilling, which is provided with the molded product as defined in claim 11.
